(19) United States
(12) Patent Application Publication
(10) Pub. No.: US 2019/0074821 A1
(43) Pub. Date: Mar. 7, 2019

(54) VOLTAGE CONVERSION DEVICE AND VOLTAGE CONVERSION METHOD

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Makoto HIGASHI, Yokkaichi-shi (JP); Takenori ABE, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 16/085,004

(22) PCT Filed: Mar. 13, 2017
(86) PCT No.: PCT/JP2017/009928

§ 371 Date: Sep. 14, 2018

(30) Foreign Application Priority Data
Mar. 29, 2016 (JP) 2016-066759

(51) Int. Cl. H03K 3/017; H03K 17/64; H03K 7/08

(52) U.S. Cl. CPC H03K 3/017; H03K 7/08; H03K 17/64

(57) ABSTRACT

A voltage conversion device that includes a switching element; an inductor; a drive circuit, wherein, by turning the switching element on/off with the drive circuit with a PWM signal, an inductor current is generated to transform an input voltage and output a transformed voltage to a load; and a controller that is configured to: switch a switching frequency with the drive circuit according to a size of a current output to the load; and change a waveform of the PWM signal when the switching frequency is switched, wherein the controller is configured to change an on-time of the PWM signal, and to turn the switching element on/off.

This application is the U.S. National Phase of PCT/JP2017/009928 filed Mar. 13, 2017, which claims priority from JP 2016-066759 filed Mar. 29, 2016, the entire disclosure of which is incorporated herein by reference.

### BACKGROUND

The present disclosure relates to a voltage conversion device and a voltage conversion method.

In a device using a battery as a power source, often a DC/DC converter is provided as a power supply circuit for supplying power to a load. The DC/DC converter includes a switching element and an inductor, and by switching the switching element on/off based on a PWM signal, transforms (increases or decreases) the voltage from the battery and outputs the transformed voltage to the load. With a DC/DC converter, even if the voltage of the external battery fluctuates, a constant voltage can be applied to the load by transforming (increasing or decreasing) the voltage from the battery.

As control schemes for stabilizing the output voltage of the DC/DC converter, there are known, among others, a voltage mode control scheme of feeding back the output voltage, a current mode control scheme of feeding back an output current in addition to the output voltage.

JP H10-323027A discloses a technique of switching a switching frequency for the switching element according to the output current in order to realize a DC/DC converter capable of suppressing a ripple current and maintaining a high transformation efficiency.

### SUMMARY

A voltage conversion device according to one aspect of the present disclosure has a switching element; an inductor; a drive circuit, wherein, by turning the switching element on/off with the drive circuit with a PWM signal, an inductor current is generated to transform an input voltage and output a transformed voltage to a load; and a controller that is configured to: switch a switching frequency with the drive circuit according to a size of a current output to the load; and change a waveform of the PWM signal when the switching frequency is switched, wherein the controller is configured to change an on-time of the PWM signal, and to turn the switching element on/off.

A voltage conversion method according to one aspect of the present disclosure is a voltage conversion method performed by a voltage conversion device having a switching element, an inductor, and a drive circuit, the voltage conversion device generating, by turning the switching element on/off with the drive circuit with a PWM signal, an inductor current to transform an input voltage and output a transformed voltage to a load, the voltage conversion method including: changing a waveform of the PWM signal when a switching frequency with the drive circuit is switched according to a size of a current output to the load; changing an on-time of the PWM signal; and turning the switching element on/off.

### BRIEF DESCRIPTION OF THE DRAWINGS

FIG. 1 is a block diagram showing an exemplary configuration of a voltage conversion device according to a first embodiment of the present disclosure.

FIG. 2 is a block diagram showing a functional configuration of a control unit in the voltage conversion device.

FIG. 3 is a timing chart showing a relationship between a switching frequency, a PWM signal, and an inductor current according to a comparative example.

FIG. 4 is a timing chart showing a relationship between a switching frequency, a PWM signal, and an inductor current according to a first embodiment of the present disclosure.

FIG. 5 is a timing chart showing a relationship between a switching frequency, a PWM signal, and an inductor current before and after the switching frequency is switched, in order to explain how a change amount is derived.

FIG. 6 is a flowchart showing an operation procedure of the voltage conversion device.

FIG. 7 is a flowchart showing an operation procedure (a subroutine of step S1) of on-time calculation processing performed by a CPU.

FIG. 8 is a flowchart showing an operation procedure (a subroutine of step S2) of frequency switching processing performed by the CPU.

FIG. 9 is a timing chart showing a relationship between a switching frequency, a PWM signal, and an inductor current according to Modification 1.

FIG. 10 is a timing chart showing a relationship between a switching frequency, a PWM signal, and an inductor current according to a second embodiment of the present disclosure.

FIG. 11 is a timing chart showing a relationship between a switching frequency, a PWM signal, and an inductor current before and after the switching frequency is switched, in order to explain how a change amount is derived.

FIG. 12 is a flowchart showing an operation procedure (a subroutine of step S2) of frequency switching processing performed by the CPU.

FIG. 13 is a timing chart showing a relationship between a switching frequency, a PWM signal, and an inductor current according to Modification 2.

FIG. 14 is a timing chart showing a relationship between a switching frequency, a PWM signal, and an inductor current according to a third embodiment of the present disclosure.

FIG. 15 is a timing chart showing a relationship between a switching frequency, a PWM signal, and an inductor current according to a fourth embodiment of the present disclosure.

FIG. 16 is a timing chart showing a relationship between a switching frequency, a PWM signal, and an inductor current according to a fifth embodiment of the present disclosure.

FIG. 17 is a timing chart showing a relationship between a switching frequency, a PWM signal, and an inductor current according to a sixth embodiment of the present disclosure.

### DETAILED DESCRIPTION OF EMBODIMENTS

### Problem to be Disclosed in Disclosure

However, in a case of switching the switching frequency as with the DC/DC converter described in JP H10-323027A, there is a problem that the output voltage greatly fluctuates after switching. The voltage output from the DC/DC converter is determined by an average value of inductor current flowing through the inductor, and immediately after switching the switching frequency low and high, the inductor current is larger or smaller than the inductor current in the steady state, so the output voltage also fluctuates between high and low. As a result, there is a problem that a constant voltage cannot be stably output to the load.

An exemplary aspect of the disclosure provides a voltage conversion device and a voltage conversion method in which even if the switching frequency is switched, it is possible to suppress fluctuations in the output voltage, and possible to output a constant voltage to the load in a stable manner.

### Advantageous Effects of Disclosure

According to the disclosure of the present disclosure, if the switching frequency is switched, the waveform of the PWM signal is changed, and thus it is possible to suppress fluctuations in the output voltage after the switching frequency is switched, and to output a constant voltage to the load in a stable manner.

### DESCRIPTION OF EMBODIMENTS OF DISCLOSURE

First, embodiments of the present disclosure will be described. Also, at least portions of embodiments described below may be combined.

(1) A voltage conversion device according to one aspect of the present disclosure has a switching element, an inductor, and a drive circuit, the voltage conversion device generating, by turning the switching element on/off with the drive circuit with a PWM signal, an inductor current to transform an input voltage and output the transformed voltage to a load, the voltage conversion device including a controller for switching a switching frequency with the drive circuit according to the size of a current output to the load; and a controller for changing a waveform of the PWM signal when the the switching frequency is switched, in which the controller is configured to change an on-time of the PWM signal, and to turn the switching element on/off.

(7) A voltage conversion method according to one aspect of the present disclosure is a voltage conversion method performed by a voltage conversion device having a switching element, an inductor, and a drive circuit, the voltage conversion device generating, by turning the switching element on/off with the drive circuit with a PWM signal, an inductor current to transform an input voltage and output the transformed voltage to a load, the voltage conversion method including changing a waveform of the PWM signal when a switching frequency with the drive circuit is switched according to the size of a current output to the load; changing an on-time of the PWM signal; and turning the switching element on/off.

According to this aspect, the waveform of the PWM signal is changed when the switching frequency for the switching element is switched in order to be increased or reduced. With this change, a decrease or an increase in the average value of the inductor current after the switching frequency is switched is suppressed, and fluctuations in the output voltage after the switching frequency is switched are suppressed.

(2) It is preferable that the controller is configured to set a change amount of the waveform of the PWM signal such that a lower limit value of the inductor current immediately after the waveform is changed matches the lower limit value of the inductor current in a steady state after the switching frequency is switched.

According to this aspect, the change amount of the waveform of the PWM signal is set such that a lower limit value of the inductor current immediately after the waveform is changed matches the lower limit value in a steady state after the switching frequency is switched. Therefore, if the switching frequency is switched in order to be increased or reduced, a decrease or an increase in the average value of the inductor current after switching is efficiently suppressed.

(3) A change amount of the waveform of the PWM signal that the controller changes preferably includes at least one of the on-time of the PWM signal and a duty ratio of the PWM signal.

According to this aspect, the change amount of the waveform of the PWM signal that changes is at least one of the on-time of the PWM signal, and the duty ratio of the PWM signal. Therefore, fluctuations in the output voltage after the switching frequency is switched are reliably suppressed.

(4) It is preferable that the controller is configured to change the waveform in only one cycle of the PWM signal immediately after or immediately before the switching frequency is switched.

According to this aspect, the waveform of the PWM signal immediately after or immediately before the switching frequency is switched is changed in only one cycle of the PWM signal. Therefore, fluctuations in the output voltage after the switching frequency is switched are suppressed quickly.

(5) It is preferable that the controller is configured to change the waveform in a plurality of cycles of the PWM signal immediately after or immediately before the switching frequency is switched.

According to this aspect, the waveform of the PWM signal immediately after or immediately before the switching frequency is switched is changed in a plurality of cycles of the PWM signal. Therefore, fluctuations in the output voltage are suppressed without a large fluctuation after the switching frequency is switched.

(6) When the switching frequency is switched by the controller in order to be increased, a duty ratio of the PWM signal immediately after switching (or immediately before switching) is preferably larger than a duty ratio of the PWM signal before switching (or after switching), and when the switching frequency is switched by the controller in order to be reduced, the duty ratio of the PWM signal immediately after switching (or immediately before switching) is preferably smaller than a duty ratio of the PWM signal before switching (or after switching).

According to this aspect, if the switching frequency is switched between high and low, the duty ratio of the PWM signal immediately after switching (or immediately before switching) is made larger or smaller than that before switching (or after switching), depending on whether the switching frequency is increased or decreased. Therefore, it is possible to reliably suppress fluctuations in the output voltage after the switching frequency is switched.

### DETAILED DESCRIPTION OF EMBODIMENTS OF DISCLOSURE

Hereinafter, specific examples of a voltage conversion device and a voltage conversion method according to embodiments of the present disclosure will be described in detail with reference to drawings.

### First Embodiment

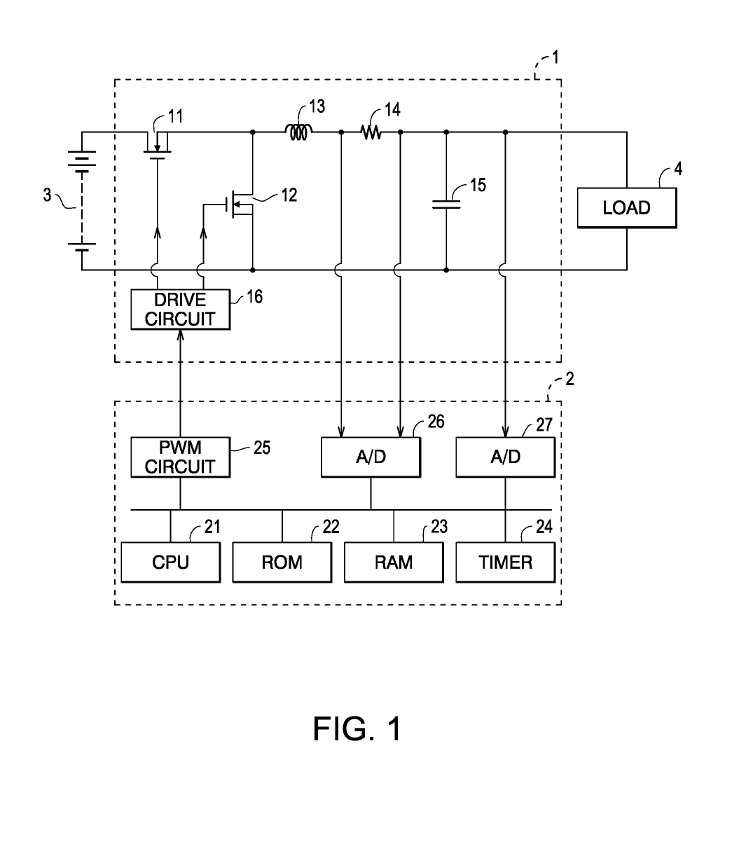

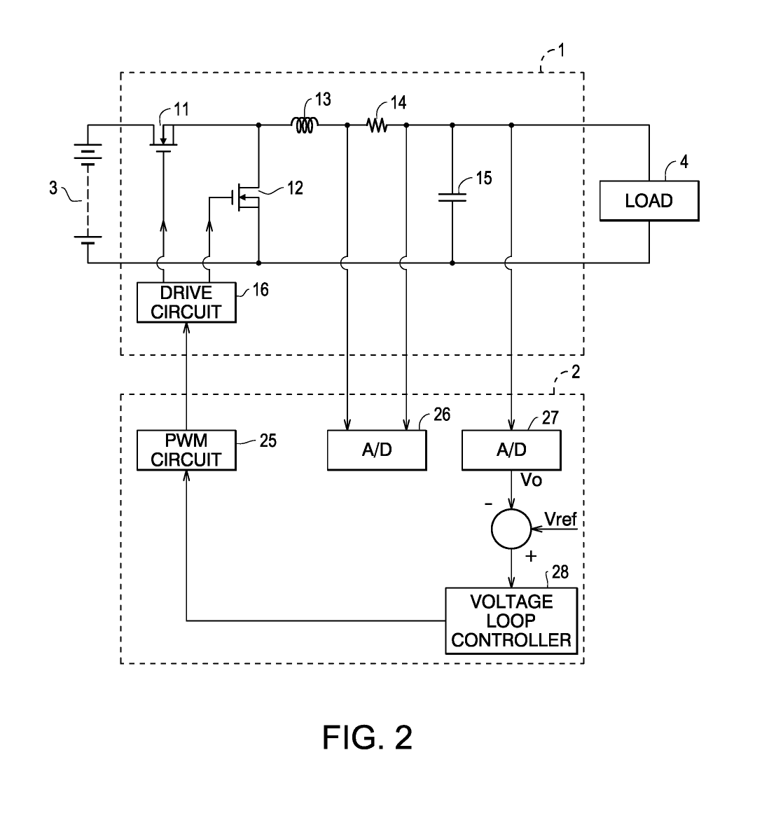

FIG. 1 is a block diagram showing an exemplary configuration of a voltage conversion device according to a first embodiment of the present disclosure, and FIG. 2 is a block diagram showing a functional configuration of a control unit 2 in the voltage conversion device. The voltage conversion device shown in FIG. 1 includes, for example, a DC/DC converter 1 that reduces the voltage of an external battery 3 and supplies this reduced voltage to a load 4, and the control unit 2, which provides a PWM signal to the DC/DC converter 1.

The DC/DC converter 1 includes a switching element 11 having one end connected to the battery 3, a second switching element 12 and an inductor 13 each having one end connected to the other end of the switching element 11, a resistor 14 having one end connected to the other end of the inductor 13, and a capacitor 15 connected between the other end of the resistor 14 and a ground potential. The other end of the second switching element 12 is connected to the ground potential. The load 4 is configured to be connected to both ends of the capacitor 15. The switching element 11 and the second switching element 12 are, for example, N-channel MOSFETs each having their drain on the one end.

The DC/DC converter 1 also includes a drive circuit 16 that provides a drive signal that turns the switching element 11 and the second switching element 12 on/off. The drive circuit 16 respectively provides a PWM signal provided from the control unit 2, and a PWM signal complementary to that PWM signal, to gates of the switching element 11 and the second switching element 12.

The control unit 2 has a CPU 21, and the CPU 21 is connected through a bus to a ROM 22 that stores a program and other information, a RAM 23 that temporarily stores generated information, and a timer 24 that clocks various time periods such as a cycle of PWM control.

The CPU 21 is also connected through a bus to a PWM circuit 25 that generates a PWM signal to be provided to the drive circuit 16, an A/D conversion circuit 26 that detects voltage across both ends of the resistor 14 and converts the current flowing through the resistor 14 into a digital current value, and an A/D conversion circuit 27 that converts the voltage across both ends of the capacitor 15 into a digital voltage value.

In FIG. 2, the control unit 2 realizes a function of a voltage loop controller 28 for controlling the output voltage to be output from the DC/DC converter 1 to the load 4 by so-called “voltage mode control”. In the drawing, the symbol “o” represents a subtractor.

Based on a deviation obtained by subtracting, from a target voltage value Vref, a digital voltage value V₀, which is obtained by converting the output voltage that was output to the load 4 with the A/D conversion circuit 27, the voltage loop controller 28 calculates an on-time of the PWM signal (unless otherwise stated, referred to as “on-time” hereinafter) and outputs the calculated on-time to the PWM circuit 25. The PWM circuit 25 generates a PWM signal having a duty ratio corresponding to the provided on-time.

In the voltage conversion device having such a configuration, the switching frequencies for the switching element 11 and the second switching element 12 are switched according to the size of the current output to the load 4 so as to result in good voltage conversion efficiency. For example, when the output current is at least 20 A, the switching frequency is set to 150 kHz, and when the output current is less than 20 A, the switching frequency is set to 100 kHz. Note that when the switching frequency is switched, the on-time calculated by the voltage loop controller 28 is also switched, but the duty ratio of the PWM signal generated in the PWM circuit 25 does not change, unless the duty ratio is corrected (this applies similarly to the other embodiments and modifications, which will be described later).

When the switching frequency is switched downward in this way, after the switching frequency is switched, the inductor current flowing through the inductor 13 becomes larger than the inductor current in the steady state, and the output voltage, which is proportional to the average value of the inductor current, also increases and fluctuates.

Therefore, in the voltage conversion device according to the first embodiment, by changing (also referred to as correcting hereinafter) the waveform of the PWM signal immediately after the switching frequency is switched, such fluctuations in the output voltage generated after the switching frequency is switched (also simply referred to as “switching” hereinafter) are suppressed.

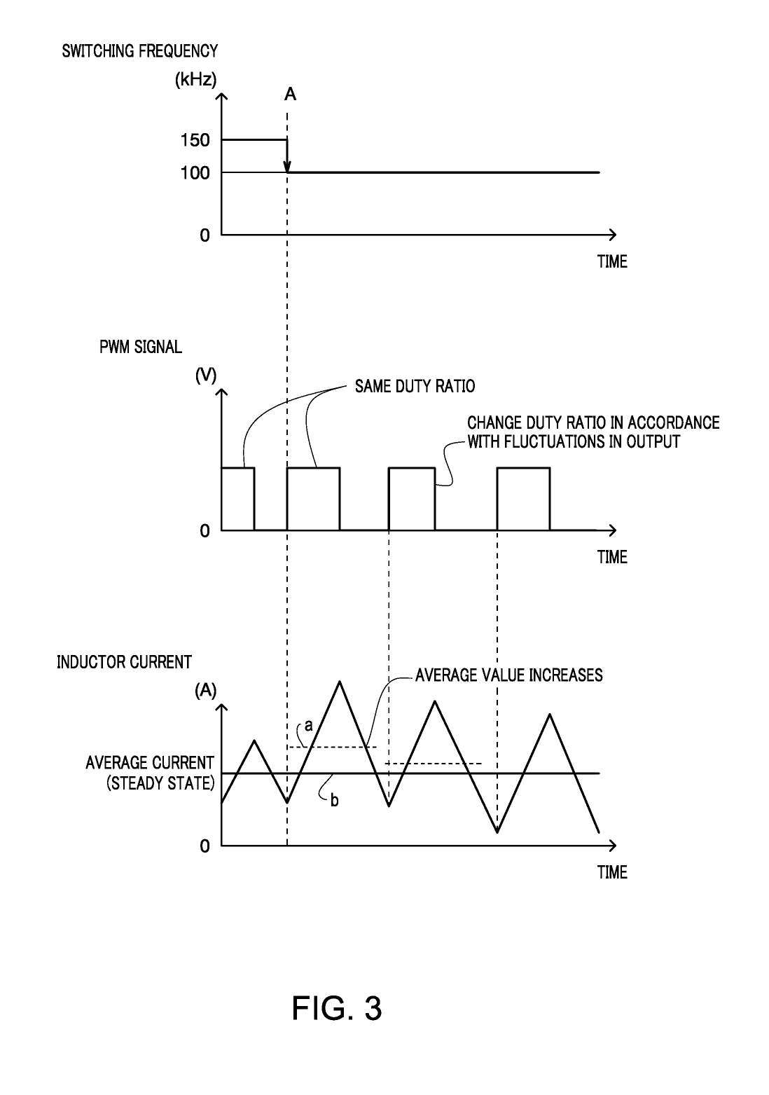

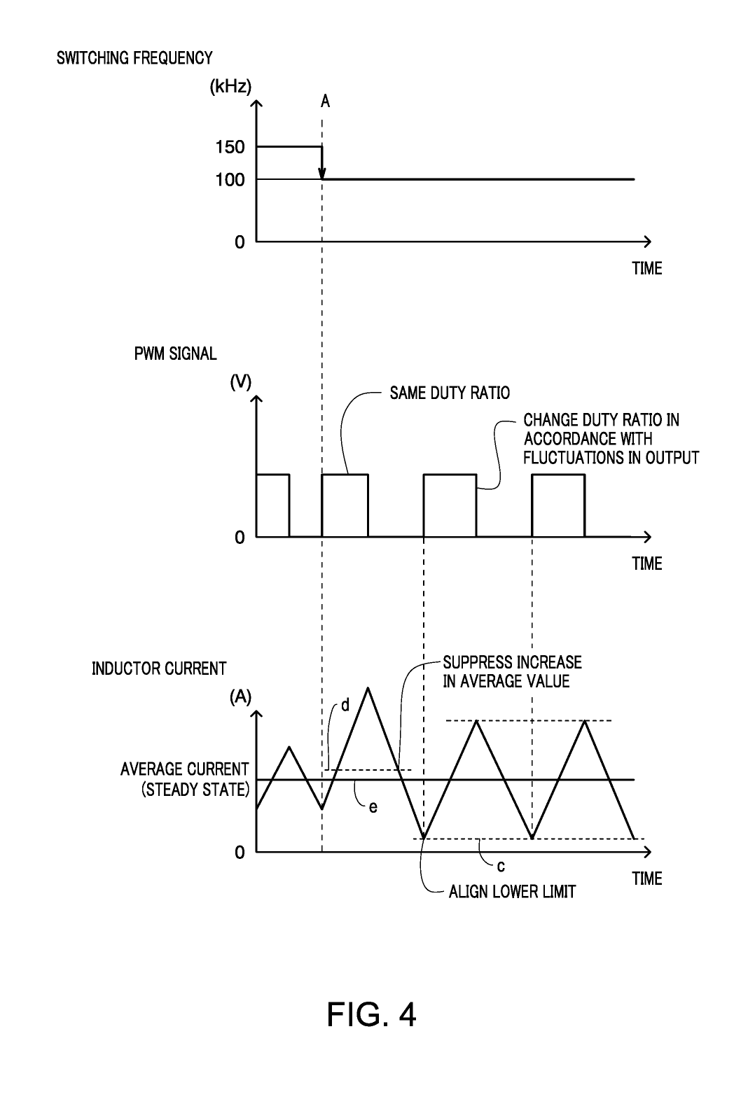

FIG. 3 is a timing chart showing a relationship between a switching frequency, a PWM signal, and an inductor current according to a comparative embodiment, and FIG. 4 is a timing chart showing a relationship between a switching frequency, a PWM signal, and an inductor current according to the first embodiment of the present disclosure. The three timing charts shown in FIGS. 3 and 4 have the same time axis as the horizontal axis. FIG. 3 shows a comparative example (conventional example) without a change as in the present disclosure, and FIG. 4 is an example according to the first embodiment of the present disclosure. In both examples, the switching frequency is switched from 150 kHz to 100 kHz at time A.

In the comparative example (conventional example) shown in FIG. 3, the duty ratio in the PWM signal immediately after switching is the same as before switching, and no change is performed. Therefore, the inductor current immediately after switching becomes large, and its average value (represented by broken line a) increases in comparison to the average value in the steady state (represented by solid line b). As a result, the output voltage also fluctuates greatly.

On the other hand, in the example of the present disclosure shown in FIG. 4, in anticipation of the change in the inductor current that accompanies switching of the switching frequency, the duty ratio in the one cycle of the PWM signal immediately after switching is changed such that the lower limit value of the inductor current immediately after switching matches the lower limit value of the inductor current in the steady state (represented by broken line c). In other words, the lower limit value of the inductor current in the cycle in which the duty ratio is changed matches the lower limit value of the inductor current in the cycles in the steady state after the switching frequency is switched.

Specifically, a correction is performed such that, in the first cycle of the PWM signal immediately after switching, the duty ratio is smaller than in the cycles before switching. Therefore, the inductor current immediately after switching does not increase greatly, and the amount of increase of that average value (represented by broken line d) with respect to the average value in the steady state (represented by solid line e) is small. As a result, fluctuations in the output voltage after switching are suppressed. Note that before and after the frequency of the PWM signal is changed, correcting (changing) the duty ratio corresponds one-to-one to changing the on-time.

Following is a description of specific values of the change amount in the waveform of the PWM signal immediately after switching, that is, specific values of the duty ratio after the waveform is changed (also simply referred to as “change” hereinafter) immediately after the switching frequency is switched, and the on-time after the change. The duty ratio D′ after the change is calculated by the following Formula (1) through a derivation process, which will be described later.

D′=[D(1−D)/2×(1/F1)+D(1+D)/2×(1/F2)]×F2=D(1−D)/2×(F2/F1)+D(1+D)/2 (1)

Note: F1 represents the switching frequency before switching,

F2 represents the switching frequency after switching, and

D represents the duty ratio before the change.

The on-time ON′ after the change is obtained by D′×(1/F2), so by substituting a relationship where D=ON×F1, with ON representing the on-time before the change, into the right side of above Formula (1) before modification, ON′ is calculated by the following Formula (2).

ON′=[ON×F1×(1−ON×F1)]/(2×F1)+[ON×F1×(1+ON×F1)]/(2×F2) (2)

If the right side in above Formula (1) after modification is regarded as a linear function of X=F2/F1, the slope obtained when this linear function is drawn on a graph is D (1−D)/2 and thus always positive, and when X=1 holds true, D′=D holds true. Therefore, if X is smaller than 1, that is, if F2 is smaller than F1, it is shown that D′ should be smaller than D, and it is confirmed that the duty ratio should be corrected such that the duty ratio in the first cycle of the PWM signal immediately after switching in FIG. 4 is smaller than that in the cycles before switching.

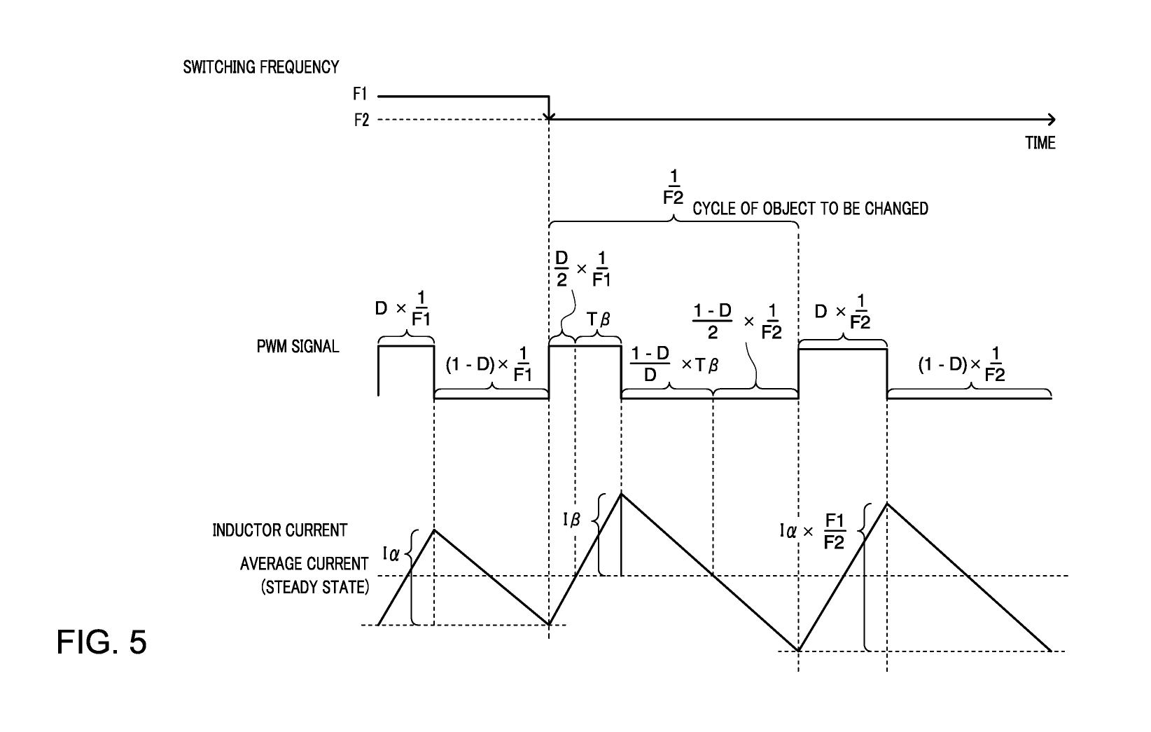

FIG. 5 is a timing chart showing a relationship between a switching frequency, a PWM signal, and an inductor current before and after the switching frequency is switched, in order to explain how a change amount is derived. The horizontal axis in FIG. 5 represents time. The process for deriving the Formula (1) above will be described with reference to FIG. 5.

The relationship between the switching frequency, the PWM signal, and the inductor current before and after the switching frequency is switched is as FIG. 5 where the width of increase of the inductor current before the switching frequency is switched is represented by Iα and the width of increase of the inductor current immediately after the switching frequency is switched is represented by (Iα/2)+Iβ. Note that in FIG. 5, Tβ indicates a portion of the on-time immediately after the switching frequency is switched.

In FIG. 5, looking at the time immediately after the switching frequency is switched from F1 to F2, the absolute value of the slope in a period during which the inductor current decreases is regarded as (1−D)/D times the slope in a period during which the inductor current increases. That is, a length of the period during which the inductor current decreases in a period during which an increase and a decrease in the inductor current cancel out is (1−D)/D times the length of the period during which the inductor current increases, and thus, a cycle 1/F2 after switching is obtained by the following Formula (3).

1/F2=(D/2)×(1/F1)+Tβ+[(1−D)/D]×Tβ+[(1−D)/2]×(1/F2) (3)

The duty ratio D′ after the change is indicated by the on-time divided by the cycle, that is, indicated by the on-time multiplied by the frequency, so D′ is obtained by the following Formula (4).

D′=[(D/2)×(1/F1)+Tβ]×F2 (4)

When above Formula (3) is solved for Tβ, the following Formula (5) is obtained.

Tβ=[D(1+D)/2]×(1/F2)−(D²/2)×(1/F1) (5)

By substituting above Formula (5) into above Formula (4), the duty ratio D′ after the change is obtained as follows, and thereby above Formula (1) is obtained.

D′=[(D/2)×(1/F1)+[D(1+D)/2]×(1/F2)(D²/2)×(1/F1)]×F2=[D(1−D)/2×(1/F1)+D(1+D)/2×(1/F2)]×F2=D(1−D)/2×(F2/F1)+D(1+D)/2

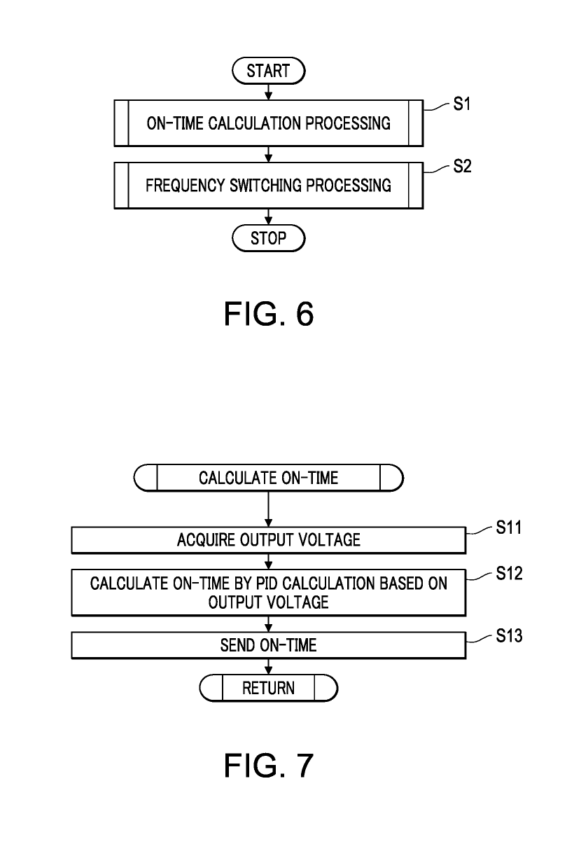

Next, the operation will be described. FIG. 6 is a flowchart showing an operation procedure of the voltage conversion device. The operation shown in FIG. 6 is performed for each control cycle of PWM control, and is executed by the CPU 21 according to a control program stored in advance in the ROM 22.

The operation of the voltage conversion device includes on-time calculation processing (step S1), which is feedback control of the PWM signal based on the detected output voltage, and frequency switching processing (step S2) in which it is determined whether or not it is necessary to switch the switching frequency, and if necessary, a change amount of the waveform in the PWM signal is calculated and switching is performed. The CPU 21 executes the processing. Following is a detailed description of the on-time calculation processing (step S1) and the frequency switching processing (step S2).

FIG. 7 is a flowchart showing an operation procedure (a subroutine of step S1) of the on-time calculation processing performed by the CPU 21.

The CPU 21 acquires the digital voltage value obtained by the A/D conversion circuit 27 converting the output voltage that was output to the load 4 (step S11). Next, based on the acquired voltage value (V₀) of the output voltage, the CPU 21 performs PID calculation such that the output voltage becomes a target voltage value (Vref), thereby calculating the on-time (step S12). The CPU 21 sends the calculated on-time to the PWM circuit 25 (step S13), and ends processing. A PWM signal is generated by the PWM circuit 25 according to the on-time that was sent.

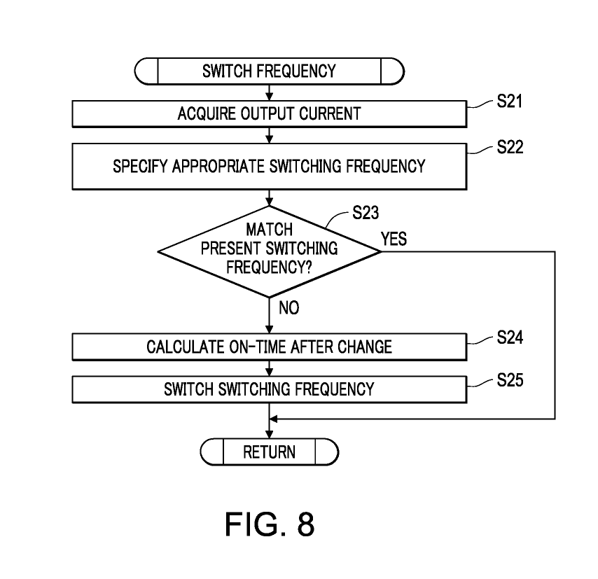

FIG. 8 is a flowchart showing an operation procedure (subroutine of step S2) of the frequency switching processing performed by the CPU 21.

If the processing in FIG. 8 is called, the CPU 21 acquires the digital current value obtained by the A/D conversion circuit 26 converting the current output to the load 4 (step S21). The CPU 21 specifies a switching frequency appropriate for the current value of the acquired output current (step S22). Specifically, when the acquired current value is at least 20 A, the CPU 21 specifies the switching frequency as 150 kHz, and when the acquired current value is less than 20 A, the CPU 21 specifies the switching frequency as 100 kHz.

The CPU 21 determines whether or not the specified switching frequency matches the present switching frequency (step S23). If they match (S23: YES), the CPU 21 ends processing.

On the other hand, if they do not match (step S23: NO), the CPU 21, according to above Formula (2), using the on-time before the change, the present switching frequency (the switching frequency before the change), and the specified switching frequency (the switching frequency after the change), calculates the on-time after the change (step S24). Then, the CPU 21 switches the present switching frequency to the specified switching frequency (step S25), and ends processing. The on-time in the first cycle immediately after the switching frequency of the PWM signal is switched is the on-time that was calculated in step S24.

In the above-described first embodiment, when the switching frequency for the switching elements 11 and 12 is switched so as to be reduced in order to increase the conversion efficiency of voltage from the battery 3, the properties (on-time or duty ratio) of the waveform of the PWM signal immediately after switching are changed, so it is possible to suppress an increase in the average value of the inductor current after switching, which is caused by the switching, and as a result, it is possible to suppress fluctuations in the output voltage, so a constant voltage can be output to the load 4 in a stable manner.

### Modification 1

The first embodiment has a configuration in which the switching frequency is switched in order to be reduced from a high frequency to a low frequency, whereas Modification 1 has a configuration in which the switching frequency is switched in order to be increased from a low frequency to a high frequency. Hereinafter, Modification 1 of the first embodiment of the present disclosure will be described. The configuration of the voltage conversion device according to Modification 1 is similar to the configuration (FIGS. 1 and 2) of the voltage conversion device according to the above-described first embodiment.

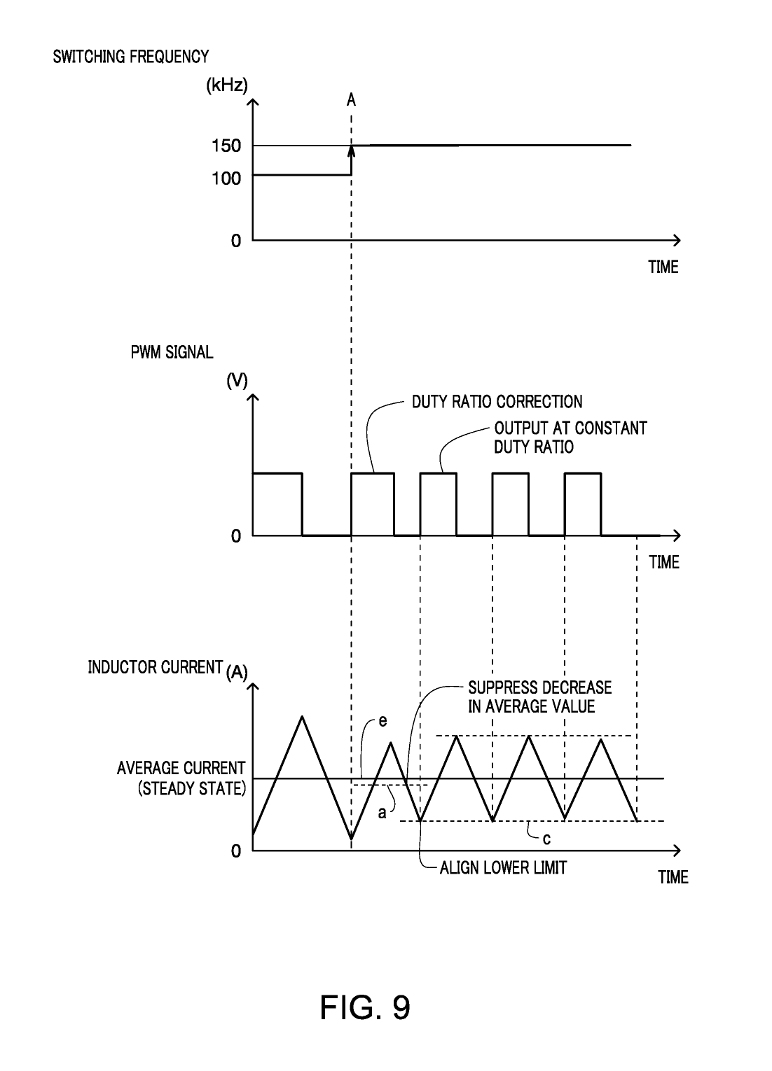

FIG. 9 is a timing chart showing a relationship between a switching frequency, a PWM signal, and an inductor current according to Modification 1. The three timing charts shown in FIG. 9 have the same time axis as the horizontal axis. In Modification 1, the switching frequency is switched from 100 kHz to 150 kHz at time A. In the example shown in FIG. 9, in anticipation of the change in the inductor current that accompanies switching of the switching frequency, the duty ratio in the one cycle of the PWM signal immediately after switching is changed such that the lower limit value of the inductor current immediately after switching matches the lower limit value of the inductor current in the steady state (represented by broken line c). In other words, the lower limit value of the inductor current in the cycle in which the duty ratio is changed matches the lower limit value of the inductor current in the cycles in the steady state after the switching frequency is switched.

Specifically, a correction is performed such that, in the first cycle of the PWM signal immediately after switching, the duty ratio is larger than in the cycles before switching. If the right side in above Formula (1) after modification is regarded as a linear function of X=F2/F1, the slope obtained when this linear function is drawn on a graph is D (1−D)/2 and thus always positive, and when X=1 holds true, D′=D holds true. Therefore, if X is larger than 1, that is, if F2 is larger than F1, it is shown that D′ should be made larger than D. If the duty ratio is corrected in this manner, the inductor current immediately after switching does not decrease excessively, and a decrease amount in the average value (represented by broken line d) with respect to the average value (represented by solid line e) in the steady state is suppressed. As a result, fluctuations in the output voltage are suppressed.

Note that in Modification 1, if the duty ratio D before the change is close to 1, D′ calculated by Formula (1) may exceed 1, but at this time, D′ should be a numerical value as close as possible to 1.

### Second Embodiment

Hereinafter, a second embodiment of the present disclosure will be described. Note that the configuration of the voltage conversion device according to the second embodiment is similar to the configuration (FIGS. 1 and 2) of the voltage conversion device according to the above-described first embodiment.

In the above-described first embodiment, the on-time in the one cycle of the PWM signal immediately after the switching frequency is switched is changed, but in the second embodiment, the on-time in the one cycle of the PWM signal immediately before the switching frequency is switched is changed. The second embodiment is suitable for cases where PWM control needs to be performed immediately after the switching frequency is switched, without any correction.

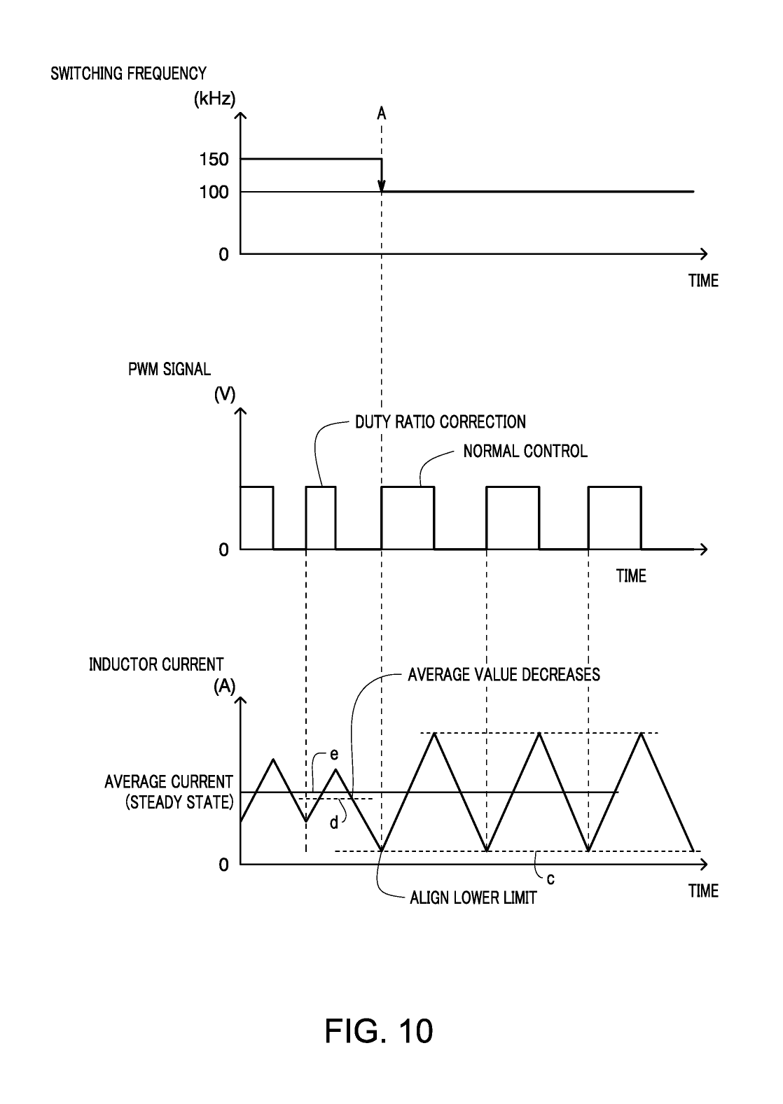

FIG. 10 is a timing chart showing the relationship between the switching frequency, the PWM signal, and the inductor current according to the second embodiment of the present disclosure. The three timing charts in FIG. 10 have the same time axis as the horizontal axis. As in the first embodiment, the switching frequency is switched from 150 kHz to 100 kHz at time A. In the example shown in FIG. 10, in anticipation of the change in the inductor current that accompanies switching of the switching frequency, the duty ratio in the one cycle of the PWM signal immediately before switching is changed such that the lower limit value of the inductor current at the time of switching matches the lower limit value of the inductor current in the steady state (represented by broken line c). In other words, the lower limit value of the inductor current in the cycle in which the duty ratio is changed matches the lower limit value of the inductor current in the cycles in the steady state after the switching frequency is switched.

Specifically, a correction is performed such that, in the one cycle of the PWM signal immediately before switching, the duty ratio is smaller than that in the previous cycles (that is, the cycles after switching). Therefore, the inductor current in the one cycle immediately before switching becomes small, and its average value (represented by broken line d) decreases suitably with respect to the average value (represented by solid line e) in the steady state. As a result, an increase in the average value of the inductor currents after switching is suppressed, and fluctuations in the output voltage after switching are suppressed.

The following is a description of specific values of the change amount in the waveform of the PWM signal immediately before switching, that is, specific values of the duty ratio after the waveform is changed immediately before the switching frequency is switched, and the on-time after the change. The duty ratio D′ after the change is calculated by the following Formula (6) through a derivation process, which will be described later.

$$\begin{matrix}{D}^{′} = [ D ( 3 - D ) \text{/} 2 \times ( 1 \text{/} F 1 ) + D ( 1 - D ) \text{/} 2 \times ( 1 \text{/} F 2 ) ] \times F 1 \\ = D ( 3 - D ) \text{/} 2 + D ( D - 1 ) \text{/} 2 \times ( F 1 \text{/} F 2 )\end{matrix} \qquad ( 6 )$$

Note: F1 represents the switching frequency before switching,

F2 represents the switching frequency after switching, and

D represents the duty ratio before the change.

The on-time ON′ after the change is obtained by D′× (1/F1), so by substituting a relationship where D=ON×F1, with ON representing the on-time before the change, into the right side of above Formula (6) before modification, ON′ is calculated by the following Formula (7).

ON′=[ON×F1×(3−ON×F1)]/(2×F1)+[ON×F1×(ON×F1−1)]/(2×F2) (7)

If the right side in above Formula (6) after modification is regarded as a linear function of Y=F1/F2, the slope obtained when this linear function is drawn on a graph is D (D−1)/2 and thus always negative, and when Y=1 holds true, D′=D holds true. Therefore, if Y is larger than 1, that is, if F2 is smaller than F1, it is shown that D′ should be made smaller than D, and it is confirmed that the duty ratio should be corrected such that the duty ratio in the one cycle of the PWM signal immediately before switching in FIG. 10 is smaller than that in the previous cycles before switching (that is, than that in the cycles after switching).

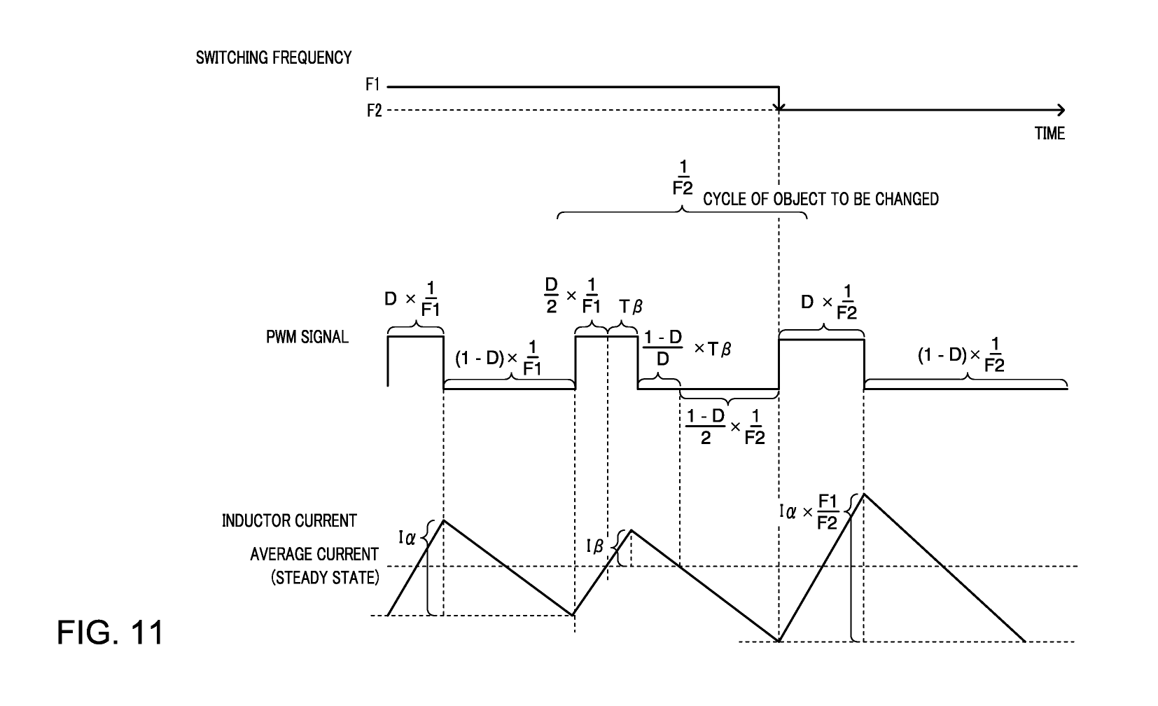

FIG. 11 is a timing chart showing a relationship between a switching frequency, a PWM signal, and an inductor current before and after the switching frequency is switched, in order to explain how a change amount is derived. The horizontal axis in FIG. 5 represents time. The process for deriving the above formula for computation will be described with reference to FIG. 11.

Similarly to the case shown in FIG. 5, the relationship between the switching frequency, the PWM signal, and the inductor current before and after the switching frequency is switched is as FIG. 11, where the width of increase of the inductor current before the switching frequency is switched is represented by Iα and the width of increase of the inductor current immediately before the switching frequency is switched is represented by (Iα/2)+Iβ. Tβ represents a part of the on-time immediately before the switching frequency is switched.

In FIG. 11, looking at the time immediately before the switching frequency is switched from F1 to F2, similarly to the case shown in FIG. 5, a length of the period during which the inductor current decreases in a period during which an increase and a decrease in the inductor current cancel out is (1−D)/D times the length of the period during which the inductor current increases, and thus, a cycle 1/F1 immediately before switching is obtained by the following Formula (8).

1/F1=(D/2)×(1/F1)+Tβ+[(1−D)/D]×Tβ+[(1−D)/2]×(1/F2) (8)

As described above, the duty ratio D′ after the change is indicated by the on-time multiplied by the frequency, so D′ is obtained by the following Formula (4) (reshown).

D′=[(D/2)×(1/F1)+Tβ]×F2 (4)

When above Formula (8) is solved for Tβ, the following Formula (9) is obtained.

Tβ=[D(2−D)/2]×(1/F1)+[D(D−1)/2]×(1/F2) (9)

By substituting Formula (9) into above Formula (4), the duty ratio D′ after the change is obtained as follows, and thereby above Formula (6) is obtained.

$$\begin{matrix}{D}^{′} = & [ ( D \text{/} 2 ) \times ( 1 \text{/} F 1 ) + [ D ( 2 - D ) \text{/} 2 ] \times ( 1 \text{/} F 1 ) + \\ & [ D ( D - 1 ) \text{/} 2 ) \times ( 1 \text{/} F 2 ) ] \times F 1 \\ = & [ D ( 3 - D ) \text{/} 2 \times ( 1 \text{/} F 1 ) + D ( D - 1 ) \text{/} 2 \times ( 1 \text{/} F 2 ) ] \times F 1\end{matrix}$$

Next, the operation will be described. A flowchart showing the operation procedure of the voltage conversion device and a flowchart showing the operation procedure (subroutine in step S1) of on-time calculation processing performed by the CPU 21 are similar to those shown in FIGS. 6 and 7 in the first embodiment, and thus their illustration and description will be omitted.

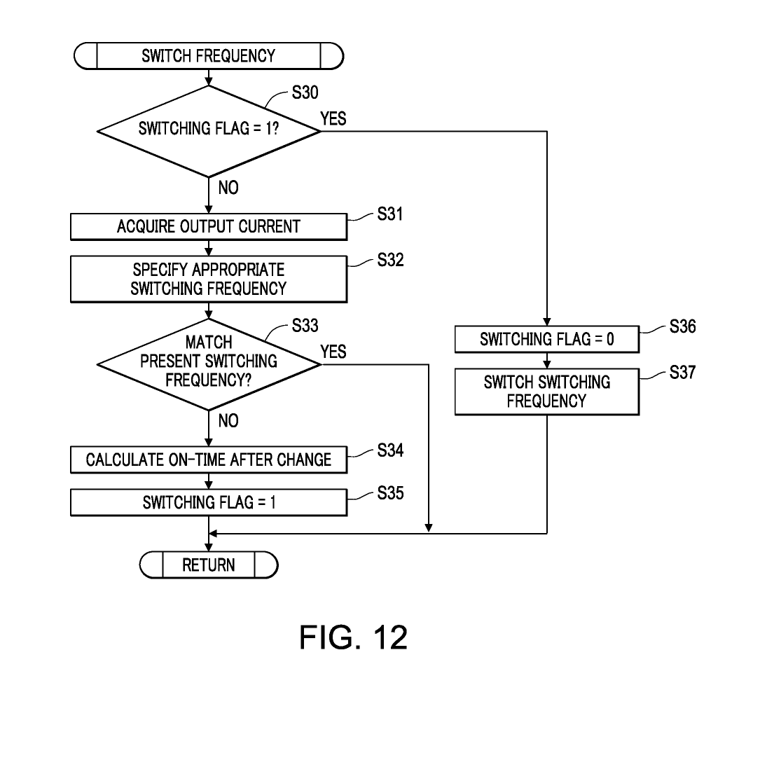

FIG. 12 is a flowchart showing an operation procedure (subroutine of step S2) of the frequency switching processing performed by the CPU 21. The switching graph in FIG. 12 is a flag showing whether or not it is a cycle to switch the switching frequency, and is stored in the RAM 23 with its initial value set to 0. The processing from step S31 to step S34 shown in FIG. 12 is similar to the processing from step S21 to step S24 shown in FIG. 8 in the first embodiment, and thus its description will be simplified.

If the processing shown in FIG. 12 is called, the CPU 21 determines whether or not the switching flag is set to 1 (step S30). If the switching flag is not set to 1 (step S30: NO), the CPU 21 acquires an output current that is output to the load 4 (step S31), and specifies the switching frequency appropriate for the acquired output current (step S32).

Next, the CPU 21 determines whether or not the specified switching frequency matches the present switching frequency (step S33), and if they match (step S33: YES), the CPU 21 ends processing.

On the other hand, if they do not match (step S33: NO), the CPU 21 calculates the on-time after the change according to above Formula (7) (step S34), sets the switching flag to 1 (step S35), and ends the processing.

If the switching flag is set to 1 in step S30 (step S30: YES), the CPU 21 clears the switching flag to 0 (step S36), then switches the present switching frequency to the specified switching frequency (step S37), and ends the processing.

In the above-described second embodiment, when the switching frequency for the switching elements 11 and 12 is switched so as to be reduced in order to increase the conversion efficiency of voltage from the battery 3, the properties (on-time or duty ratio) of the waveform of the PWM signal immediately before switching are changed, so it is possible to suppress an increase in the average value of the inductor currents after switching, which is caused by the switching, and as a result, it is possible to suppress fluctuations in the output voltage, so a constant voltage can be output to the load 4 in a stable manner.

Note that in the second embodiment, if the duty ratio D before the change is close to 0, D′ calculated by Formula (6) may be less than 0, but at this time, D′ should be a numerical value as close as possible to 0.

### Modification 2

The second embodiment has a configuration in which the switching frequency is switched in order to be reduced from a high frequency to a low frequency, whereas Modification 2 has a configuration in which the switching frequency is switched in order to be increased from a low frequency to a high frequency. Hereinafter, Modification 2 of the second embodiment of the present disclosure will be described. The configuration of the voltage conversion device according to Modification 2 is similar to the configuration (FIGS. 1 and 2) of the voltage conversion device according to the above-described first embodiment.

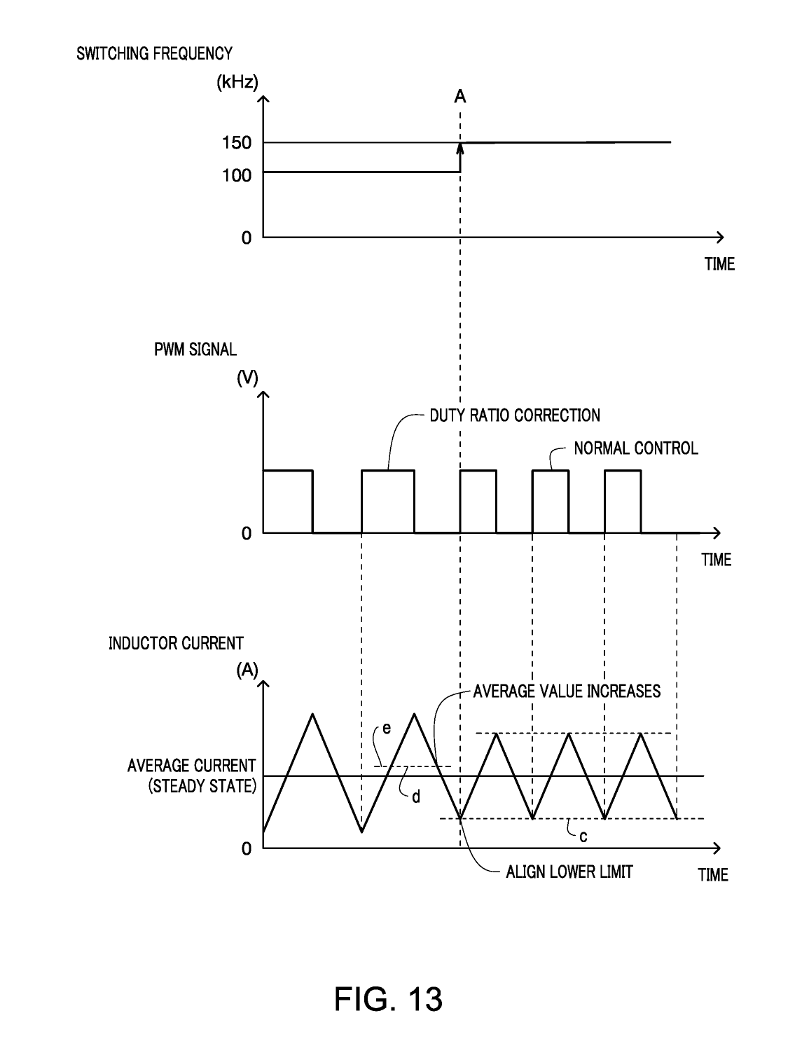

FIG. 13 is a timing chart showing a relationship between a switching frequency, a PWM signal, and an inductor current according to Modification 2. The three timing charts in FIG. 13 have the same time axis as the horizontal axis. In Modification 2, the switching frequency is switched from 100 kHz to 150 kHz at time A. In the example shown in FIG. 13, in anticipation of the change in the inductor current that accompanies switching of the switching frequency, the duty ratio in the one cycle of the PWM signal immediately before switching is changed such that the lower limit value of the inductor current at the time of switching matches the lower limit value of the inductor current in the steady state (represented by broken line c). In other words, the lower limit value of the inductor current in the cycle in which the duty ratio is changed matches the lower limit value of the inductor current in the cycles in the steady state after the switching frequency is switched.

Specifically, a correction is performed such that, in the one cycle of the PWM signal immediately before switching, the duty ratio is larger than that in the previous cycles (that is, the cycles after switching). If the right side in above Formula (6) after modification is regarded as a linear function of Y=F1/F2, the slope obtained when this linear function is drawn on a graph is D (D−1)/2 and thus always negative, and when Y=1 holds true, D′=D holds true. Therefore, if Y is smaller than 1, that is, if F2 is larger than F1, it is shown that D′ should be made larger than D. If the duty ratio is corrected in this manner, the inductor current immediately before switching increases, and its average value (represented by broken line d) increases suitably with respect to the average value (represented by solid line e) in the steady state. As a result, a decrease in the average value of the inductor currents after switching is suppressed, and fluctuations in the output voltage are suppressed.

### Third Embodiment

Hereinafter, a third embodiment of the present disclosure will be described. Note that the configuration of the voltage conversion device according to the third embodiment is similar to the configuration (FIGS. 1 and 2) of the voltage conversion device according to the above-described first embodiment.

Although in the above-described first and second embodiments, only the on-time in the one cycle of the PWM signal immediately after and immediately before the switching frequency is switched is changed, the on-time in a plurality of cycles of the PWM signal immediately after the switching frequency is switched is changed in the third embodiment. This third embodiment is suitable for cases where feedback control based on the output voltage is not performed in each cycle of the PWM signal.

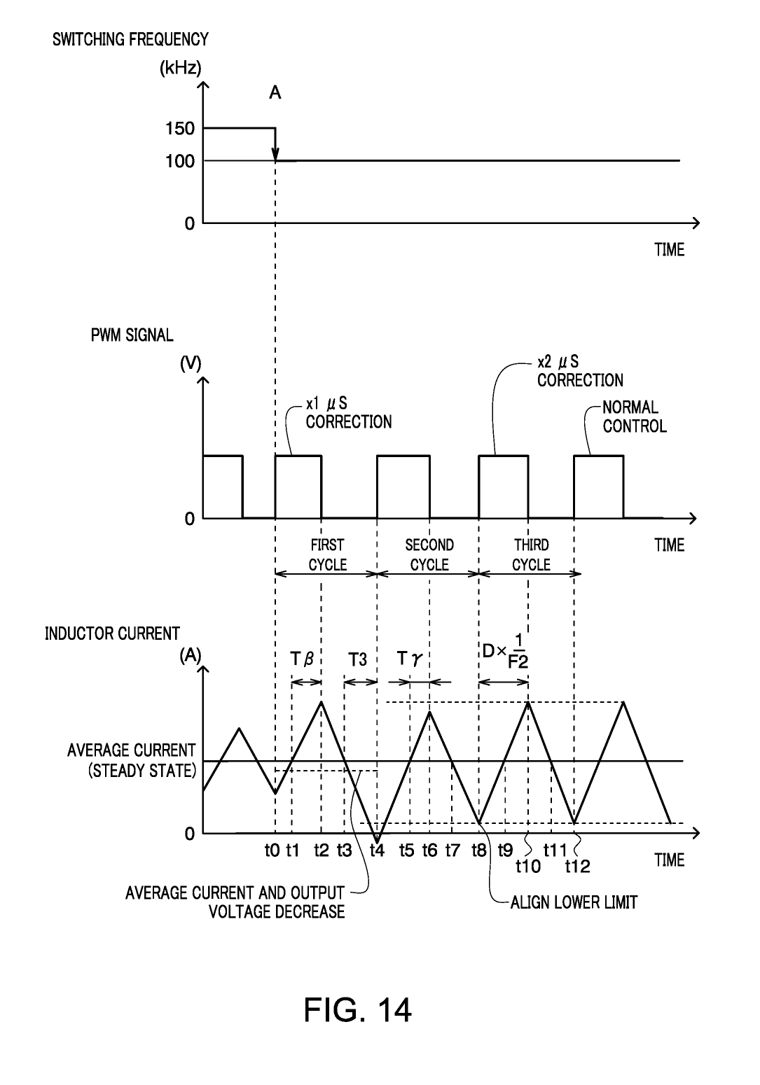

FIG. 14 is a timing chart showing the relationship between the switching frequency, the PWM signal, and the inductor current according to the third embodiment of the present disclosure. The three timing charts in FIG. 14 have the same time axis as the horizontal axis. As in the first embodiment, the switching frequency is switched from 150 kHz to 100 kHz at time A. In the example shown in FIG. 14, the on-time is changed in two cycles immediately after the switching frequency is switched. That is, in the first cycle immediately after the switching frequency is switched, the on-time is changed by x1 μs such that the upper limit value of the inductor current matches the upper limit value of the inductor current in the steady state, in the second cycle, the on-time is changed by x2 μs such that the lower limit value of the inductor current matches the lower limit value of the inductor current in the steady state, and in the third cycle onward, normal control is performed. In other words, the upper limit value of the inductor current in the first and second cycles in which the duty ratio is changed matches the lower limit value of the inductor current in the cycles in the steady state after the switching frequency is switched.

A specific change amount of the on-time will be described using FIG. 14 with reference to FIG. 5. In FIG. 14, the time when the switching frequency is switched is regarded as t0 and the time when the inductor current matches an average current immediately after time t0 is regarded as t1. Afterwards, the time when the inductor current successively matches an average current is regarded as t3, t5, t7, t9, and t11, and the time when the inductor current successively becomes a local maximum and a local minimum is regarded as t2, t4, t6, t8, t10, and t12.

A time period from time t 1 to time t2 corresponds to Tβ in FIG. 5, and a time period from time t8 to time t10 corresponds to D×1/F2 in FIG. 5. In the present third embodiment, control is performed such that the inductor current at time t2 and the inductor current at time t10 are equal to each other, so that the Formula (10) below holds true. Also, as described above, the duty ratio D′ after the change is indicated by the on-time multiplied by the frequency, so D′ is obtained by the following Formula (4) (reshown).

Tβ=(D/2)×(1/F2) (10)

D′=[(D/2)×(1/F1)+T1β]×F2 (4)

By substituting Formula (10) into Formula (4), the duty ratio D′ in the first cycle (from time t0 to time t4) after the switching frequency is switched is obtained as the Formula (11) below. The product obtained by multiplying, by the cycle (1/F2), the second term on the right side that was modified last in this Formula (11) is a correction amount (corresponds to the above-described x1 μs) of the on-time of the PWM signal from time t0 to time t2. If the switching frequency is switched from 150 kHz to 100 kHz, that is, if F2/F1 is smaller than 1, the duty ratio immediately after switching is corrected so as to be smaller than that before switching. In this case, a correction is performed such that x1 is a negative number, and the on-time of the PWM signal immediately after switching is shorter than the on-time in the steady state after switching.

$$\begin{matrix}{D}^{′} = [ ( D \text{/} 2 ) \times ( 1 \text{/} F 1 ) + ( D \text{/} 2 ) \times ( 1 \text{/} F 2 ) ] \times F 2 \\ = ( D \text{/} 2 ) \times ( F 2 \text{/} F 1 + 1 ) \\ = D - ( D \text{/} 2 ) \times ( 1 - F 2 \text{/} F 1 )\end{matrix} \qquad ( 11 )$$

The following is a description of a correction amount of the PWM signal in the second cycle (from time t4 to time t8) after the switching frequency is switched. In the first cycle after the switching frequency is switched, as shown in Formula (11), the duty ratio D′ is corrected to be smaller than D, and thus a time period from time t2 to time t4 is longer than a time period from time t10 to time t12 in the normal control with the frequency F2, and accordingly, the inductor current decreases excessively by this amount.

When a time period from time t3 to time t4 in the first cycle is regarded as T3, similarly to the case of FIG. 5, a time period from time t0 to time t1 is (D/2)×(1/F1). Also, similarly to a time period from time t9 to time t11, a time period from time t1 to time t3 is (½)×(1/F2) that corresponds to half of one cycle. Because a time period from time t0 to time t4 is 1/F2, T3 is obtained by the following Formula (12).

T3=(½)×(1/F2)−(D/2)×(1/F1) (12)

Next, a time period from time t5 to time t6 in the second cycle is regarded as T_{Y}. As described above, a length of the period during which the inductor current decreases in a period during which an increase and a decrease in the inductor current cancel out is (1−D)/D times the length of the period during which the inductor current increases, and thus, the time period from time t4 to time t5 in the second cycle is D/(1−D) times T3, and the time period from time t6 to time t7 is (1−D)/D times Tβ. Also, a time period from time t7 to time t8 is [(1−D)/2]×(1/F2), and thus, with regard to the overall time period of the second cycle, the following Formula (13) holds true.

1/F2=T3×D/(1−D)+T_{Y}+[(1−D)/D]×T_{Y}+[(1−D)/2]×(1/F2) (13)

The duty ratio after the change is indicated by the on-time divided by the cycle, that is, indicated by the on-time multiplied by the frequency from time t4 to time 6, so the duty ratio D″ after the change is obtained by the following Formula (14).

D″=[T3×D/(1−D)+T_{Y}]×F2 (14)

When the above Formula (13) is solved for T_{Y}, the following Formula (15) is obtained.

T_{Y}=[D(1+D)/2]×(1/F2)−T3×D²/(1−D) (15)

By substituting, into Formula (14), above Formula (12) and a formula obtained by substituting Formula (12) into above Formula (15), the duty ratio D″ after the change is obtained as Formula (16) below. However, a description of the intermediate results of modification of the formula will be omitted. The product obtained by multiplying, by the cycle (1/F2), the second term on the right side that was modified last in this Formula (16) is a correction amount (corresponds to the above-described x2 μs) of the PWM signal from time t4 to time t6. If the switching frequency is switched from 150 kHz to 100 kHz, that is, if F2/F1 is smaller than 1, a correction is performed such that the duty ratio in the second cycle after switching is larger than that in the cycles before switching. In this case, a correction is performed such that x2 is a positive number, and the on-time of the PWM signal in the second cycle after switching is longer than the on-time in the cycles in the steady state after switching.

$$\begin{matrix}{D}^{″} = [ - ( {D}^{2} \text{/} 2 ) \times ( 1 \text{/} F 1 ) + ( D \text{/} 2 ) \times ( 2 + D ) \times ( 1 \text{/} F 2 ) ] \times F 2 \\ = D + ( {D}^{2} \text{/} 2 ) \times ( 1 - F 2 \text{/} F 1 )\end{matrix} \qquad ( 16 )$$

If the right side in above Formula (11) after modification (or Formula (16) is regarded as a linear function of X=F2/F1, the slope obtained when this linear function is drawn on a graph is D/2 (or −(D²/2) and thus always positive (or negative), and when X=1 holds true, it is shown that D′=D(D″=D) holds true. Therefore, if X is smaller than 1, that is, if F2 is smaller than F1, it is shown that D′ should be made smaller than D (or D″ should be made larger than D), and it is confirmed that the duty ratio should be corrected such that the duty ratio in the first cycle (or the second cycle) of the PWM signal immediately after switching in FIG. 14 is smaller (or larger) than that in the cycles before switching.

Also, if X=F2/F1 is larger than 1 in Formula (11) (or Formula (16)), that is, if F2 is larger than F1, it is shown that D′ should be made larger than D (or D″ should be made smaller than D). That is, a correction is performed such that, in the first cycle (or the second cycle) of the PWM signal immediately after switching, the duty ratio is larger (or smaller) than that in the cycles before switching.

As described above, in the third embodiment, the output voltage fluctuates such that the output voltage decreases instead of increasing, and thus, if the switching frequency is switched, the risk is eliminated that the output voltage exceeds the upper limit voltage indicated in the specification.

Note that if the on-time is changed for at least three cycles immediately after the switching frequency is switched, the transition of the inductor current after the switching frequency is switched is anticipated, and the calculation should be performed similarly to the above-described third embodiment, based on this anticipated result, using the switching frequency before switching, the switching frequency after switching, and the duty ratio before the change, such that the upper limit value or the lower limit value of the inductor current matches the upper limit value or the lower limit value of the inductor current in the steady state.

Also, in the third embodiment, if X=F2/F1 is larger than 1 and the duty ratio D before the change is close to 1, D′ calculated by Formula (11) may exceed 1 in some cases, and in this case, D′ should be a numerical value that is extremely close to 1, for example, D″ should be D, for example.

### Fourth Embodiment

Hereinafter, a fourth embodiment of the present disclosure will be described. Note that the configuration of the voltage conversion device according to the fourth embodiment is similar to the configuration (FIGS. 1 and 2) of the voltage conversion device according to the above-described first embodiment. The third embodiment has a configuration in which the length of the on signal of the PWM signal for two cycles immediately after the switching frequency is switched is corrected, whereas the fourth embodiment has a configuration in which the length of the on signal of the PWM signal for two cycles immediately before the switching frequency is switched is corrected.

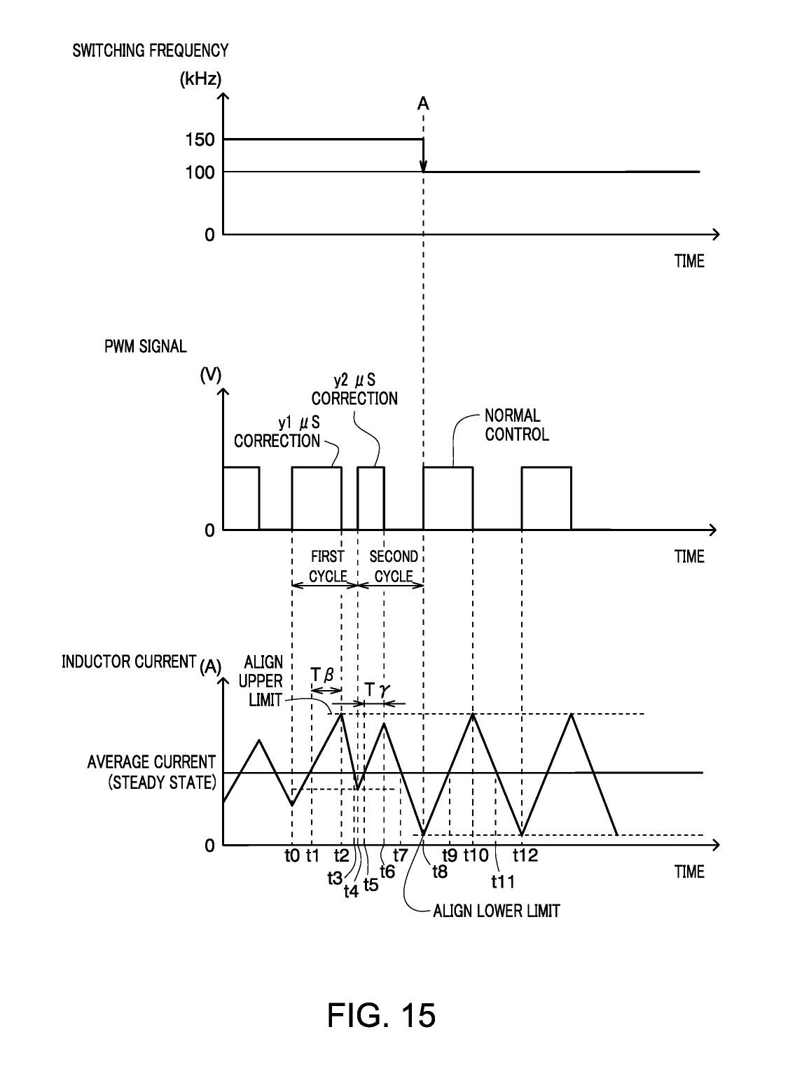

FIG. 15 is a timing chart showing the relationship between the switching frequency, the PWM signal, and the inductor current according to the fourth embodiment of the present disclosure. The three timing charts in FIG. 15 have the same time axis as the horizontal axis. As in the first embodiment, the switching frequency is switched from 150 kHz to 100 kHz at time A. In the example shown in FIG. 15, the on-time is changed for two cycles of the PWM signal immediately before switching. That is, in the two cycles immediately before the switching frequency is switched, in the first cycle (from time t0 to time t4), the on-time is changed by y1 μs such that the upper limit value of the inductor current matches the upper limit value of the inductor current in the steady state, in the second cycle (from time t4 to time t8), the on-time is changed by y2 μs such that the lower limit value of the inductor current matches the lower limit value of the inductor current in the steady state, and normal control is performed immediately after switching. In other words, the upper limit value and the lower limit value of the inductor current in the first and second cycles in which the duty ratio is changed respectively match the upper limit value and the lower limit value of the inductor current in the cycles in the steady state after the switching frequency is switched.

A specific change amount of the on-time will be described using FIG. 15 with reference to FIG. 5. In FIG. 15, a time that is two cycles before the time when the switching frequency is switched is regarded as to, and a time when the inductor current matches an average current immediately after time t0 is regarded as t1. Afterwards, the time when the inductor current successively matches the average current is regarded as t3, t5, t7, t9, and t11, and the time when the inductor current successively becomes a local maximum and a local minimum is regarded as t2, t4, t6, t8, t10, and t12. The time when the switching frequency is switched is time t8.

A time period from time t1 to time t2 corresponds to Tβ in FIG. 5, and a time period from time t8 to time t10 corresponds to D×1/F2 in FIG. 5. In the present fourth embodiment, control is performed such that the inductor current at time t2 and the inductor current at time t10 are equal to each other, so that the Formula (10) (reshown) below holds true. Also, as described above, the duty ratio D′ after the change is indicated by the on-time multiplied by the frequency, so D′ is obtained by the following Formula (17).

Tβ=(D/2)×(1/F2) (10)

D′=[(D/2)×(1/F1)+Tβ]×F1 (17)

By substituting Formula (10) into Formula (17), the duty ratio D′ in the first cycle out of the two cycles immediately before the switching frequency is switched is obtained as the following Formula (18) below. The product obtained by multiplying, by the cycle (1/F1), the second term on the right side that was modified last in this Formula (18) is a correction amount (corresponds to the above-described y1 μs) of the PWM signal from time t0 to time t2. If the switching frequency is switched from 150 kHz to 100 kHz, that is, if F1/F2 is larger than 1, a correction is performed such that the duty ratio in the first cycle out of the two cycles immediately before switching is larger than that in the cycles before the previous cycles (that is, the cycles after switching). In this case, a correction is performed such that y1 is a positive number, and the on-time of the PWM signal in the first cycle out of the two cycles immediately before switching is longer than the on-time in the steady state after switching.

$$\begin{matrix}{D}^{′} = [ ( D \text{/} 2 ) \times ( 1 \text{/} F 1 ) + ( D \text{/} 2 ) \times ( 1 \text{/} F 2 ) ] \times F 1 \\ = ( D \text{/} 2 ) \times ( 1 + F 1 \text{/} F 2 ) \\ = D - ( D \text{/} 2 ) \times ( 1 - F 1 \text{/} F 2 )\end{matrix} \qquad ( 18 )$$

The following is the description of a correction amount of the PWM signal in the second cycle out of the two cycles immediately before the switching frequency is switched. When a time period from time t3 to time t4 in the first cycle is regarded as T3 (not shown: see FIG. 14), similarly to the case of FIG. 5, a time period from time t0 to time t1 is (D/2)×(1/F1). Also, similarly to a time period from time t9 to time t11, a time period from time t1 to time t3 is (½)×(1/F2) that corresponds to half of one cycle. Because the time period from time t0 to time t4 is 1/F1, T3 is obtained by the following Formula (19).

$$\begin{matrix}T 3 = ( 1 \text{/} F 1 ) - ( 1 \text{/} 2 ) \times ( 1 \text{/} F 2 ) - ( D \text{/} 2 ) \times ( 1 \text{/} F 1 ) \\ = ( 2 - D ) \text{/} 2 \times ( 1 \text{/} F 1 ) - ( 1 \text{/} 2 ) \times ( 1 \text{/} F 2 )\end{matrix} \qquad ( 19 )$$

Next, a time period from time t5 to time t6 in the second cycle is regarded as T_{Y}. As described above, a length of the period during which the inductor current decreases in a period during which an increase and a decrease in the inductor current cancel out is (1−D)/D times the length of the period during which the inductor current increases, and thus, a time period from time t4 to time t5 in the second cycle is D/(1−D) times T3, and the time period from time t6 to time t7 is (1−D)/D times T_{Y}. Also, a time period from time t7 to time t8 is [(1−D)/2]×(1/F1), and thus, with regard to the overall time period of the second cycle, the following Formula (20) holds true.

1/F1=T3×D/(1−D)+T_{Y}+[(1−D)/D]×T_{Y}+[(1−D)/2]×(1/F1) (20)

The duty ratio after the change is indicated by the on-time divided by the cycle, that is, indicated by the on-time multiplied by the frequency from time t4 to time 6, so the duty ratio D″ after the change is obtained by the following Formula (21).

D″=[T3×D/(1−D)+T_{Y}]×F1 (21)

When above Formula (20) is solved for T_{Y}, the following Formula (22) is obtained.

T_{Y}=[D(1+D)/2]×(1/F1)−T3×D²/(1−D) (22)

By substituting, into Formula (21), above Formula (19) and a formula obtained by substituting Formula (19) into above Formula (22), the duty ratio D″ after the change is obtained as Formula (23) below. However, a description of the intermediate results of modification of the formula will be omitted. The product obtained by multiplying, by the cycle (1/F1), the second term on the right side that was modified last in this Formula (23) is a correction amount (corresponds to the above-described y2 μs) of the PWM signal from time t4 to time t6. If the switching frequency is switched from 150 kHz to 100 kHz, that is, if F1/F2 is larger than F1, a correction is performed such that the duty ratio in the first cycle out of the two cycles immediately before switching is smaller than that in the previous cycles (that is, cycles after switching). In this case, a correction is performed such that y2 is a negative number, and the on-time of the PWM signal in the second cycle out of the two cycles immediately before switching is shorter than the on-time in the steady state after switching.

$$\begin{matrix}{D}^{″} = [ 3 \times D \text{/} 2 \times ( 1 \text{/} F 1 ) ] \times F 1 - [ ( D \text{/} 2 ) \times ( 1 \text{/} F 2 ) ] \times F 1 \\ = D + ( D \text{/} 2 ) \times ( 1 - F 1 \text{/} F 2 )\end{matrix} \qquad ( 23 )$$

If the right side after modification in above Formula (18) (or Formula (23)) is regarded as a linear function of Y=F1/F2, it is shown that the slope obtained when this linear function is drawn on a graph is D/2 (or −D/2) and thus always positive (negative), and when Y=1 holds true, it is shown that D′=D(D″=D) holds true. Therefore, if Y is larger than 1, that is, if F2 is smaller than F1, it is shown that D′ should be made larger than D (or D″ should be made smaller than D), and it is confirmed that a correction should be performed such that the duty ratio in the first cycle (or the second cycle) out of the two cycles immediately before switching in FIG. 15 is larger (or smaller) than that in the previous cycles, that is, in the cycles after switching.

Also, if Y=F1/F2 is smaller than 1 in Formula (18) (or Formula (23)), that is, if F2 is larger than F1, it is shown that D′ should be made smaller than D (or D″ should be made larger than D). That is, a correction should be performed such that the duty ratio in the first cycle (or the second cycle) out of the two cycles immediately before switching is smaller (or larger) than that in the cycles after switching.

As described above, in the fourth embodiment, the output voltage fluctuates such that the output voltage decreases instead of increasing, and thus, if the switching frequency is switched, the risk is eliminated that the output voltage will exceed the upper limit voltage indicated in the specification.

Note that in the fourth embodiment, if Y=F1/F2 is larger than 1 and the duty ratio D before the change is close to 1, D′ calculated by Formula (18) may exceed 1 in some cases, and in this case, D′ should be a numerical value that is extremely close to 1, for example, D″ should be D, for example.

### Fifth Embodiment

Hereinafter, a fifth embodiment of the present disclosure will be described. Note that the configuration of the voltage conversion device according to the fifth embodiment is similar to the configuration (FIGS. 1 and 2) of the voltage conversion device according to the above-described first embodiment.

In the above-described first embodiment, only the on-time in the one cycle of the PWM signal immediately after the switching frequency is switched is changed, but in the fifth embodiment, the frequency in the one cycle of the PWM signal immediately after the switching frequency is switched is changed. This fifth embodiment can also be regarded as a configuration in which the frequency in the one cycle of the PWM signal immediately before the switching frequency is switched is changed.

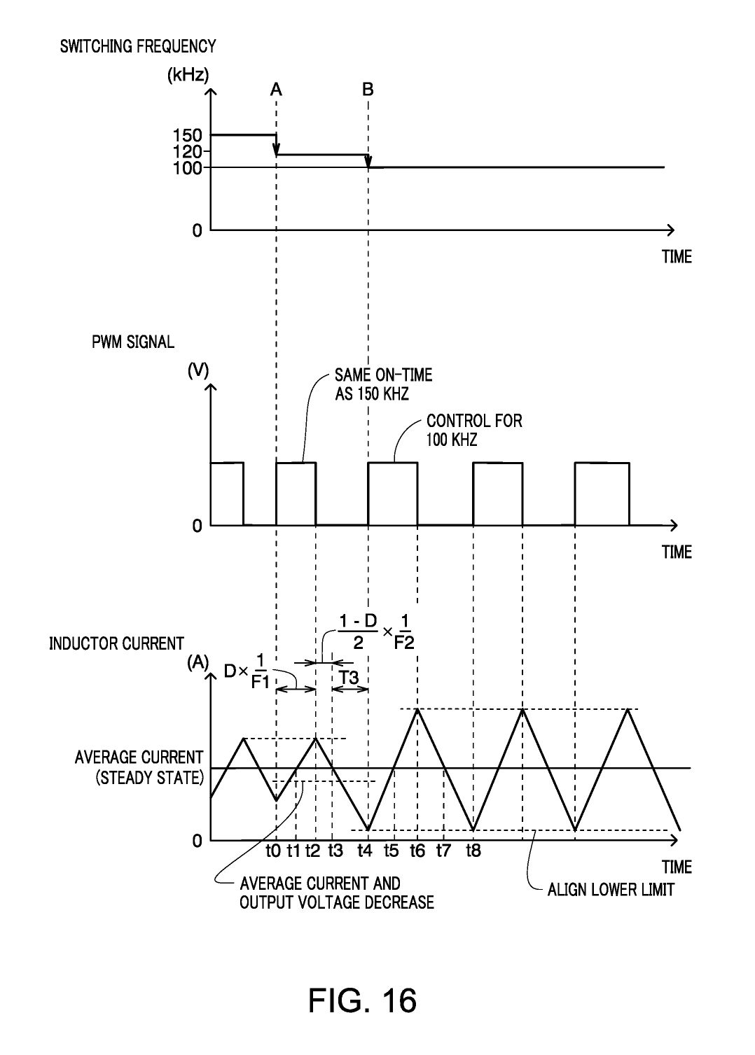

FIG. 16 is a timing chart showing the relationship between the switching frequency, the PWM signal, and the inductor current according to the fifth embodiment of the present disclosure. The three timing charts in FIG. 16 have the same time axis as the horizontal axis. As in the first embodiment, the switching frequency is switched at time A (or time B). When doing so, in the example shown in FIG. 16, in only one cycle immediately after the switching frequency is switched (or immediately before switching), the on-time is not changed but rather the frequency of the PWM signal is set to 120 kHz, and from the second cycle onward (or after switching), the frequency of the PWM signal is set to 100 kHz.

In this way, in the fifth embodiment, in order for the lower limit value of the inductor current immediately after the switching frequency is switched (or immediately before switching) to be aligned with the lower limit value in the steady state, immediately after the switching frequency is switched (or immediately before switching), the on-time of the PWM signal is not changed, but rather, the frequency of the PWM signal is changed. In other words, the lower limit value of the inductor current in the cycle in which the frequency of the PWM signal is changed matches the lower limit value of the inductor current in the cycles in the steady state after the switching frequency is switched.

A specific change amount of the frequency will be described using FIG. 16 with reference to FIG. 5. In FIG. 16, the time when the switching frequency is switched is regarded as t0 (or t4) and the time when the inductor current matches an average current immediately after t0 is regarded as t1. Afterwards, the time when the inductor current successively matches an average current is regarded as t3, t5, and t7, and the time when the inductor current successively becomes a local maximum and a local minimum is regarded as t2, t4, t6, and t8.

A time period from time t0 to time t2 corresponds to D×(1/F1) before the switching frequency is switched in FIG. 5. Also, a time period from time t2 to time t3 corresponds to half of (1−D)×(1/F1) before the switching frequency is switched in FIG. 5. A time period from time t0 to time t4 is 1/F2. Therefore, when a time period from time t3 to time t4 is regarded as T3, T3 is obtained by the following Formula (24).

T3=(1/F2)−D×(1/F1)−[(1−D)/2]×(1/F1) (24)

Note: F1 represents the switching frequency before switching,

F2 represents the switching frequency immediately after switching (or immediately before switching), and

D represents duty ratio.

In the present fifth embodiment, because control is performed such the the inductor current at time t4 is equal to the inductor current at time t8, the depth of a valley of the inductor current at time t4 (a difference between the average current and the local minimum) is equal to the depth of a valley of the inductor current at time t8. The depth of these valleys is equal to the mountain height of the inductor current at time t6 (a difference between the average current and the local maximum).

Here, when the switching frequency in the second cycle onward (or after switching) after switching is regarded as F3, a ratio of the mountain height of the inductor current at time t6 with respect to the mountain height of the inductor current at time t2 is equal to the ratio of F1 with respect to F3, and thus, the ratio of T3 with respect to the time period from time t2 to time t3 is equal to the ratio of F1 with respect to F3, and the following Formula (25) holds true.

[(1−D)/2]×(1/F1)/T3=F3/F1 (25)

When Formula (24) is substituted into Formula (25) and the Formula (25) is solved for F2, the following Formula (26) is obtained. This F2 should be the switching frequency of the one cycle immediately after the switching frequency is switched (or immediately before switching).

F2=2×F1×F3/[(1−D)×F1+(1+D)×F3] (26)

### Sixth Embodiment

Hereinafter, a sixth embodiment of the present disclosure will be described. Note that the configuration of the voltage conversion device according to the sixth embodiment is similar to the configuration (FIGS. 1 and 2) of the voltage conversion device according to the above-described first embodiment.

Although in the above-described first and second embodiments, only the on-time in the one cycle of the PWM signal immediately after and immediately before the switching frequency is switched is changed, the on-time in the one cycle of the PWM signal immediately before and immediately after the switching frequency is switched is changed in the sixth embodiment. This sixth embodiment is suitable for cases where feedback control based on the output voltage is not performed in each cycle of the PWM signal.

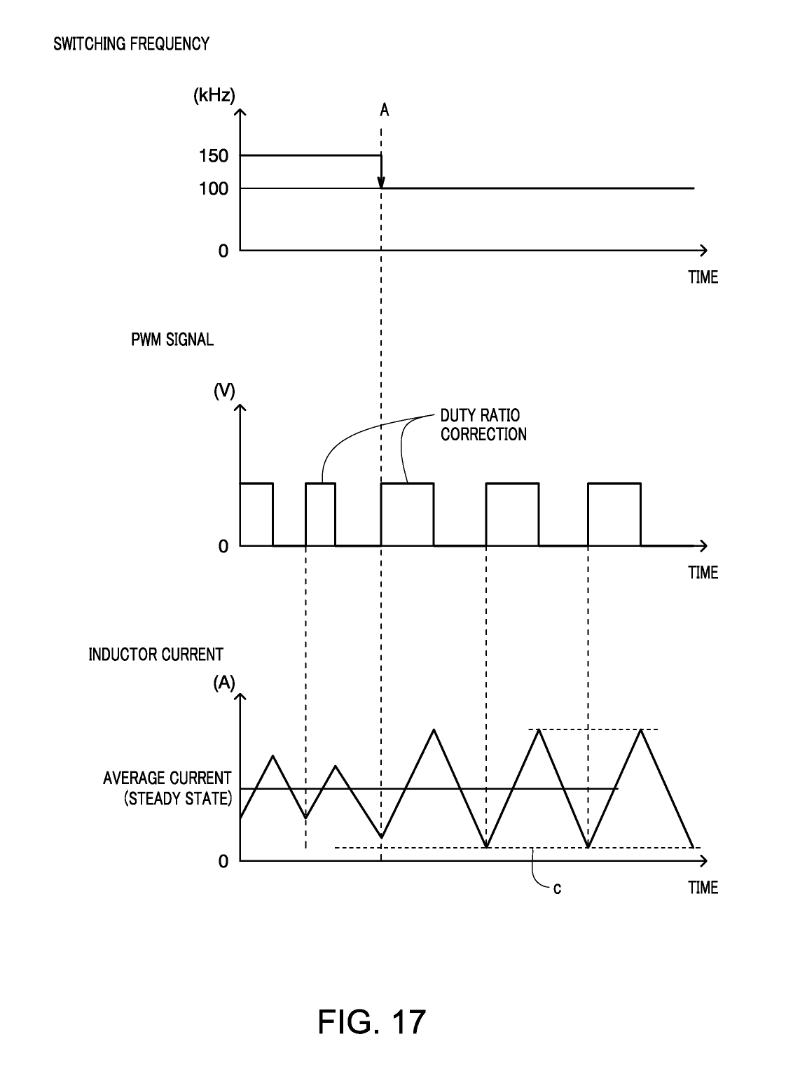

FIG. 17 is a timing chart showing the relationship between the switching frequency, the PWM signal, and the inductor current according to the sixth embodiment of the present disclosure. The three timing charts in FIG. 17 have the same time axis as the horizontal axis. As in the fourth embodiment, the switching frequency is switched from 150 kHz to 100 kHz at time A. In the example shown in FIG. 17, in anticipation of the change in the inductor current that accompanies switching of the switching frequency, the duty ratio in the one cycle of the PWM signals immediately before switching and immediately after switching is changed such that the local minimum of the inductor current at the end of the one cycle immediately after switching approximately matches the lower limit value of the inductor current in the steady state (represented by broken line c). In other words, the lower limit value of the inductor current in the second cycle in which the duty ratio is changed approximately matches the lower limit value of the inductor current in the cycles in the steady state after the switching frequency is switched.

Specifically, if the switching frequency is switched from a high frequency to a low frequency (or from a low frequency to a high frequency), a correction is performed such that, in the one cycle of the PWM signals immediately before switching and immediately after switching, the duty ratio is smaller (or larger) than that in the cycles in the steady state. Therefore, the average value of the inductor currents in the one cycle before switching and immediately after switching decreases (or increases) suitably, and as a result of which, the lower limit value of the inductor current in the one cycle immediately after the duty ratio is changed approximately matches the lower limit value of the inductor current in the cycles in the steady state after switching.

The following is a description of specific values of the change amount in the waveform of the PWM signal immediately before switching and immediately after switching, that is, specific values of the duty ratio immediately before and immediately after the switching frequency is switched, and the on-time after the change. A duty ratio D_ after the change is calculated using an arithmetic average of the duty ratio D before the change and D′ indicated by Formula (1) or Formula (6) (the duty ratio that was corrected after the switching frequency is switched or before the switching frequency is switched), by the following Formula (27) or Formula (28).

D_=[D+[D(1−D)/2×(1/F1)+D(1+D)/2×(1/F2)]×F1]/2 (27)

D_=[D+[D(3−D)/2×(1/F1)+D(D−1)/2×(1/F2)]×F1]/2 (28)

Because the on-time ON_ after the change is obtained by D_× (1/F1), when the on-time before the change is ON, by substituting the relationship D=ON×F1 into above Formula (27) or above Formula (28), ON_ can be calculated by the following Formula (29) or Formula (30) below.

ON_=[ON×F1+[ON×F1×(1−ON×F1)]/(2×F1)+[ON×F1×(1+ON×F1)]/(2×F2) (29)

ON_=[ON×F1+[ON×F1×(3−ON×F1)]/(2×F1)+[ON×F1×(ON×F1−1)]/(2×F2) (30)

Note that although the duty ratio D_ of the PWM signal immediately before switching and immediately after switching is calculated using an arithmetic average of D and D′ in the sixth embodiment, D_ may also be calculated based on an geometrical average of D and D′ or an average value of D and D′.

### Seventh Embodiment

In the above-described fifth embodiment, the frequency is changed without changing the on-time immediately after the switching frequency is switched (or immediately before switching), but as a mode in which the first (or second) and fifth embodiments are combined, it is also possible to simultaneously change the on-time and the frequency immediately after the switching frequency is switched (or immediately before switching), and align the lower limit of the inductor current immediately after the waveform of the PWM signal is changed with the lower limit value of the inductor current after the switching frequency is switched, in the steady state.

Note that in the first to sixth embodiments and the Modifications 1 and 2, a case is described in which the switching frequency is switched from 150 kHz to 100 kHz or from 100 kHz to 150 kHz according to the size of the output current, but this is given as an example, and the present disclosure is likewise applicable to a case in which, for example, the switching frequency is switched from 125 kHz to 110 kHz or from 110 kHz to 125 kHz. That is, regarding the numerical values of the switching frequencies before and after switching according to the size of the output current, the numerical values described in this specification are merely examples, and the present disclosure is compatible with changing from a numerical value to a numerical value, according to the product form of the voltage conversion device where the disclosure is applied.

Also, in the first to sixth embodiments and Modifications 1 and 2, a case is described of using voltage mode control of feeding back a detected output voltage, but the present disclosure is likewise applicable to a case of using current mode control of feeding back a detected output current in addition to an output voltage.

Furthermore, a case is described in which the DC/DC converter 1 reduces the voltage of the battery 3 and supplies this reduced voltage to the load 4, but the DC/DC converter 1 also may increase the voltage of the battery 3, or may increase or decrease the voltage of the battery 3.

The embodiments and modifications disclosed in this application are to be considered in all respects as illustrative and not restrictive. The scope of the present disclosure is indicated by the scope of the claims rather than by the meaning of the above description, and all changes that come within the meaning and range of equivalency of the claims are intended to be embraced therein. Also, technical features described in the respective embodiments can be combined with each other.

1. A voltage conversion device comprising:
a switching element;
an inductor;
a drive circuit, wherein, by turning the switching element on/off with the drive circuit with a PWM signal, an inductor current is generated to transform an input voltage and output a transformed voltage to a load; and
a controller that is configured to:
switch a switching frequency with the drive circuit according to a size of a current output to the load; and
change a waveform of the PWM signal when the switching frequency is switched,
wherein the controller is configured to change an on-time of the PWM signal, and to turn the switching element on/off.

2. The voltage conversion device according to claim 1,
wherein the controller is configured to set a change amount of the waveform of the PWM signal such that a lower limit value of the inductor current immediately after the waveform is changed matches the lower limit value of the inductor current in a steady state after the switching frequency is switched.

3. The voltage conversion device according to claim 1,
wherein a change amount of the waveform of the PWM signal that the controller changes includes at least one of the on-time of the PWM signal and a duty ratio of the PWM signal.

4. The voltage conversion device according to claim 1,
wherein the controller is configured to change the waveform in only one cycle of the PWM signal immediately after or immediately before the switching frequency is switched.

5. The voltage conversion device according to claim 1,
wherein the controller is configured to change the waveform in a plurality of cycles of the PWM signal immediately after or immediately before the switching frequency is switched.

6. The voltage conversion device according to claim 1,
wherein when the switching frequency is switched by the controller in order to be increased, a duty ratio of the PWM signal immediately after switching is larger than a duty ratio of the PWM signal before switching, and
when the switching frequency is switched by the controller in order to be reduced, the duty ratio of the PWM signal immediately after switching is smaller than a duty ratio of the PWM signal before switching.

7. A voltage conversion method performed by a voltage conversion device having a switching element, an inductor, and a drive circuit, the voltage conversion device generating, by turning the switching element on/off with the drive circuit with a PWM signal, an inductor current to transform an input voltage and output a transformed voltage to a load, the voltage conversion method comprising:
changing a waveform of the PWM signal when a switching frequency with the drive circuit is switched according to a size of a current output to the load;
changing an on-time of the PWM signal; and
turning the switching element on/off.

8. The voltage conversion device according to claim 1,
wherein when the switching frequency is switched by the controller in order to be increased, a duty ratio of the PWM signal immediately before switching is larger than a duty ratio of the PWM signal after switching, and
when the switching frequency is switched by the controller in order to be reduced, the duty ratio of the PWM signal immediately before switching is smaller than a duty ratio of the PWM signal after switching.
